(19) United States
(12) Patent Application Publication
(10) Pub. No.: US 2016/0017602 A1
(43) Pub. Date: Jan. 21, 2016

(54) Substrate for a sensitive floor and method for displaying loads on one substrate

(71) Applicant: Claudio LUCCHESE, Maranello (mo) (IT)

(72) Inventors: Claudio Lucchese, Maranello (MO) (IT); Rita Cucchiara, Modena (IT); Martino Lombardi, L'Aquila (IT); Augusto Pieracci, Castel San Pietro Terme (BO) (IT); Paolo Santinelli, Castelfranco Emilia (MO) (IT); Roberto Vezzani, Correggio (RE) (IT)

(73) Assignee: Claudio Lucchese, Maranello (MO) (IT)

(21) Appl. No.: 14/773,374

(22) PCT Filed: Mar. 14, 2014
(86) PCT No.: PCT/IB2014/059784

§ 371 Date: Sep. 7, 2015

(30) Foreign Application Priority Data
Mar. 15, 2013 (IT) MO2013A000067

(51) Int. Cl. E04B 5/43; H05K 7/18; G01N 27/04; E04B 5/46

(52) U.S. Cl. CPC E04B 5/43; E04B 5/46; H05K 7/18; G01N 27/041

(57) ABSTRACT

As substrate for making a sensitive floor includes a first frame made of high-conductivity sensing elements having a first orientation; a second frame made of high-conductivity sensing elements, which is adapted to be laid on the first frame and has a second orientation, other than the first orientation, the second frame forming a support layer for floor finishing products; and an element made of a conductive material, which includes an elastically compressible layer having a thickness, two opposite faces contacting the first and second frames, and an electric resistor whose resistance is proportional to the thickness.

### FIELD OF THE INVENTION

The invention relates to a substrate for making a sensitive floor and a method for continuous sensing and display of loads on the substrate, which can be generally used for detecting both static and dynamic stresses on the floor, and transducing them into continuous or substantially continuous signals transmitted to a continuous electronic display device.

### BACKGROUND ART

So-called “sensitive floors” have been known, which can detect the presence of moving or stationary people and things thereupon.

These floors generally consist of a network of pressure signal carrying cables or bands, with sensors located at their knots.

This network typically extends directly on the base foundation of a surface that is designed to become a floor, the latter being finished by usual finishing products, typically in the form of tiles or slabs of various types, laid on the sensors, such that as they are walked upon, they press on the sensors which in turn generate a pressure signal that propagates through the network and reaches a computer having a program for converting the received signals into two-dimensional or three-dimensional graphics, to be readily and continuously displayed on the monitor typically used by the computer.

A floor of this type is known from Patent Application PCT WO 2012/050606, which relates to a sensing apparatus using tiles, a sensor that has a plate and object identification set for multi-touch surfaces, and a method therefor.

This document discloses a thick network of signal-carrying cables intersecting to form rows and columns, thereby forming a grid that is designed to be placed on a general support surface, typically the base foundation, and has a plurality of intersection meshes and knots.

Pressure sensors are mounted at these knots, for sensing a load that is transferred thereto by the tiles that form the flooring surface, as they are walked upon, or by a stationary load on the floor.

All the ends of the cables join into terminal connectors, which are further connected to transmission cables that carry the grid signals to a computer having a data processing program that allows continuous display of graphics representing the loads on the floor and their changes according to load displacements.

In other words, information may be continuously projected on a monitor, e.g. about load distribution throughout the areas of the floor as a person walks thereon, or about a person in a stationary position on the floor, e.g. standing or lying thereon, for instance after an accidental fall, or about the speed at which he/she moves on the floor, and else.

The above described prior art suffers from certain drawbacks.

A first drawback is that detailed and prompt detection requires a network with a great number of knots, and hence sensors, such that the entire surface of the floor, or at least most of it, can sense the loads acting thereupon without leaving insensitive areas.

This requires the use of both a multitude of sensors and a proportional number of transmission cables, which largely affects the general cost for making a sensitive floor.

Furthermore, the floor surface is required to have as few discontinuities as possible, such that signal continuity may be maintained when pressing both a tile and those contiguous thereto.

Another drawback is that particular structural arrangements are required between the bottom surfaces of the tiles and the contact surfaces of sensors for load stresses to be transferred in conditions as close as possible to the actual value.

Thus, the bottom surfaces of the tiles are required to have particular profiles, i.e. with support ridges designed to be precisely located at the vertical of the sensors, to properly press thereupon.

A further problem is that the large amount of transmission cables that form the networks creates particularly bulky connection terminals, which cannot be easily concealed within the overall floor thickness.

Yet another problem is that, if one of the transmission cables is accidentally broken, the whole network becomes inactive and the floor will be no longer able to sense and transmit signals, and to provide any of its functions.

A further problem is that a sensitive floor requires careful, scrupulous and inalterable assembly, as the ridge elements of the bottom faces of the finishing tiles and the sensors must be located in vertically matching positions, to avoid the risk of providing an imperfect floor having sensitive and insensitive areas, if such positions do not match.

Another problem is that prior art sensitive floors have considerable overall thicknesses due to the ridges formed at the knots of the signal transmission networks where sensors are mounted, which are designed to be pressed upon by corresponding ridges of the bottom faces of the surface finishing tiles.

Yet another problem is that prior art networks have a rigid structure, which is hardly manipulated during the laying process.

Therefore, they have to be specially prepared according to the size of the surfaces to be covered, and they have to be carried in flat, assembled and bulky form, and will not be easily mounted, due to the difficulty of mating the various components.

### DISCLOSURE OF THE INVENTION

One object of the invention is to improve the prior art.

Another object of the invention is to provide a substrate for making a sensitive floor that can be used both as a newly supplied component, and to convert existing static floors into sensitive floors.

A further object of the invention is to provide a substrate for making a sensitive floor that has a simplified construction as compared with the prior art, and can be thus manufactured at a lower cost.

Another object of the invention is to provide a substrate for making a sensitive floor that requires no particular care in the laying process, as it may be manipulated as a normal sheath, and that can operate properly even in case of partial damage.

A further object of the invention is to provide a substrate for making a sensitive floor that can be carried as a normal carpet, in rolled and easy-to-handle form.

Another object of the invention is to provide a substrate for making a sensitive floor that allows quick and removable mounting of any kind of finishing product thereon.

Yet another object of the invention is to provide a method for continuous sensing and display of loads acting upon a sensitive substrate for making a sensitive floor, that can show the load stresses applied to the substrate.

A further object of the invention is to provide a method for continuous sensing and display of loads acting upon a sensitive substrate, that can make information available for any further processing.

In one aspect the invention provides a substrate for making a sensitive floor as defined by the features described hereinafter.

In another aspect the invention provides a method for continuous sensing and display of loads acting upon a sensitive substrate for making a sensitive floor as defined by the features described hereinafter.

The invention achieves the following advantages:

making sensitive floors in shorter times and at lower costs as compared with the prior art;

converting existing inert floors into sensitive floors;

maintaining the sensitive floors in operation even when some part of the substrate is damaged;

avoiding the need of providing products with special profiles to make contact at point-like sensors of signal carrying cable grids;

providing a substantially seamless sensing surface;

considerably reducing the overall thickness of sensitive floors;

allowing any kind of desired finishing product to be quickly and removably mounted to the substrate;

carrying the substrate as a normal carpet, e.g. rolled into tubular form.

### BRIEF DESCRIPTION OF THE DRAWINGS

Further characteristics and advantages of the invention will be more apparent from the detailed description of a preferred, non-exclusive embodiment of a substrate for making a sensitive floor, which is shown as non-limiting example in the annexed drawings, in which:

FIG. 1 is a perspective view of a portion of a substrate for making a sensitive floor according to the invention;

FIG. 2 is a plan view of the portion of FIG. 1;

FIG. 3 is a general schematic view of a substrate for making a sensitive floor;

FIG. 4 is a perspective broken-away view of a second embodiment of a substrate for making a sensitive floor according to the invention;

FIG. 5 is a broken-away enlarged view of a longitudinal section of the substrate of FIG. 1, as taken along a plane V-V, with no load acting thereupon;

FIG. 6 is a broken-away enlarged view of a longitudinal section of the substrate of FIG. 1, as taken along a plane V-V, with the load of the foot of a walking person acting thereupon;

FIG. 7 is a broken-away enlarged view of a cross section of the substrate of FIG. 4, as taken along a plane VII-VII;

FIG. 8 is a broken-away enlarged view of a cross section of the substrate of FIG. 4, as taken along a plane VIII-VIII.

### DETAILED DESCRIPTION OF PREFERRED EMBODIMENTS

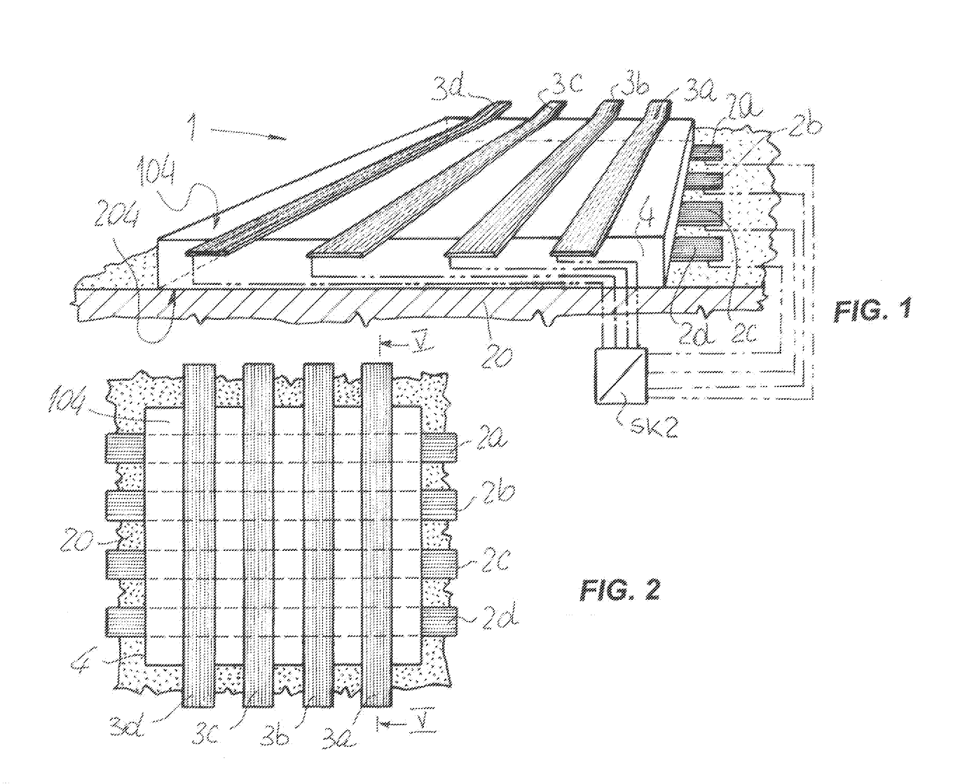

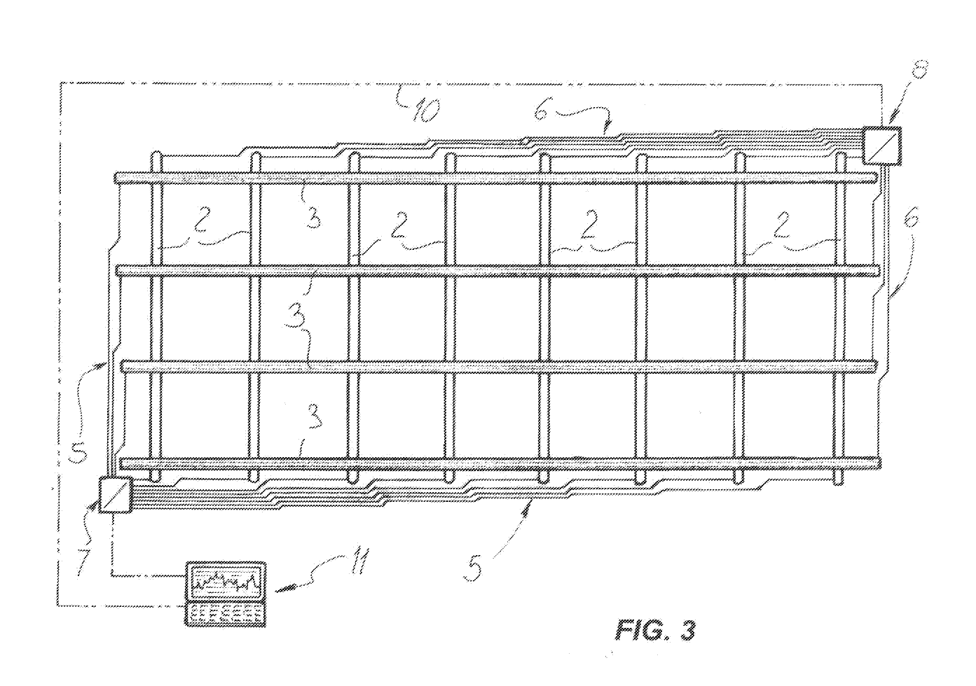

Referring now to FIGS. 1-3, numeral 1 designates a first embodiment of a substrate, or a module to make a larger substrate, for making a sensitive floor, i.e. a floor that can continuously sense the stresses acting thereupon, and send the signals generated by these stresses to a computer 11 that has a program for promptly and continuously displaying the changes of these stresses on a monitor, in graphics forms.

The substrate 1 is preferably provided in the form of a flexible sheath, and may have a custom perimeter, or be divided into two or more modular elements that can be joined together side-by-side to form a large complete substrate.

The substrate 1 comprises a first frame of sensing means, which are preferably but without limitation made of parallel thin strips of a high-conductivity material, such as aluminum, having a first common orientation and referenced 2a-2d, whose number may change as needed.

The substrate 1 also comprises a second frame of sensing means, which is also provided in the form of parallel thin aluminum strips, and hence has a high conductivity, these means being oriented according to a second common orientation, which is different from said first orientation and preferably perpendicular thereto, and being referenced 3a to 3d according to their number, which also may change as needed.

A sheet 4 is arranged between the first frame of strips 2a-2d and the second frame of strips 3a-3d, which is made of a conductive polymer material, having the following illustrative properties:

a resistivity ranging from 300 KΩ×m to 400 KΩ×m, namely 350 KΩ×m;

a thickness “S1” ranging from 2 to 4 mm, namely 3 mm.

The skilled person will understand that any polymeric or even non-polymeric material having these or equivalent properties may be used to form the sheet 4.

It shall be noted that the first frame of strips 2 is designed to lay directly on the base foundation 20 of a building structure designed to become a walkable and sensitive floor.

Both the first frame of strips 2a-2d and the second frame of strips 3a-3d have respective cables, generally referenced 5 and 6, which carry the stress signals of each strip, generated by walking or by the stationary presence of persons and/or things, and which join into separate and independent connectors 7 and 8.

These connectors 7 and 8 are connected to corresponding lines 9 and 10 for connection to the computer 11, as better explained hereinafter.

In order to form a complete sensitive floor, finishing products (not shown and irrelevant for the invention), e.g. selected from the group comprising tiles, slabs, planks, carpeting, are laid above the second frame of strips 3a-3d, to form the exposed, walkable surface of the sensitive floor.

For this purpose, the top face of the substrate may be equipped with a layer of a pressure-sensitive, pull-out adhesive, generally known as Velcro®, not shown being well known to the skilled person.

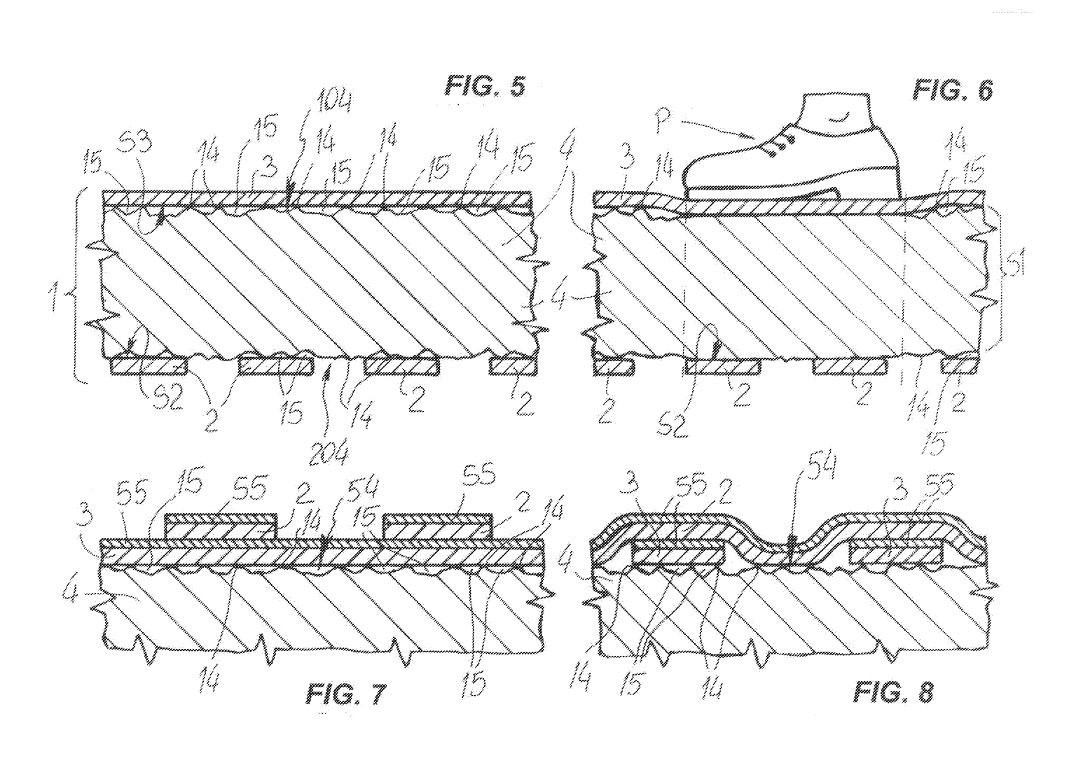

More in detail, referring to FIGS. 5 and 6, both the first frame of strips 2a-3d and second frame of strips 3a-3d lay on respective opposite faces of the sheet 4, referenced 104 and 204, which define the thickness “S1”.

These faces have a raised surface roughness 14, that may be either inherent to the polymeric material that forms the sheet 4 or specially formed as the latter is molded.

While this raised roughness 14 has a small height, it still forms a multitude of support and bearing points for contact surfaces “S2” and “S3” of the conductive strips 2a-2d and 3a-3d and defines concave areas 15 between the support points in which, when the substrate 1 has no load acting thereupon, the faces 104, 204 do not contact the strips 2a-2d and 3a-3d.

Particularly referring to FIG. 6, it will be appreciated that, when a load acts upon the substrate 1, the surface roughness 14 is compressed by the strips 3a-3d in the area in which a compression force is exerted, e.g. by a foot “P” of a walking person, and their contact surface “S3” is lowered until it rests upon the corresponding face 104 of the sheet 4, thereby creating a contact surface whose overall area is considerably larger than that of the contact surface created in the unloaded state, thereby generating a contact electrical resistance that is considerably lower the typical value of the floor in the unloaded state.

Referring back to FIG. 1, the strips 2a-2d and 3a-3d are shown to be connected to an electronic board “SK2”, which can provide both a power supply to each strip from any known source, e.g. an accumulator battery or a power line or energy harvesting, and stop such power supply in a programmed succession, and furthermore collect signals for any change of current through the strips 2a-2d and 3a-3d and send them to the computer 11, as better described hereinafter.

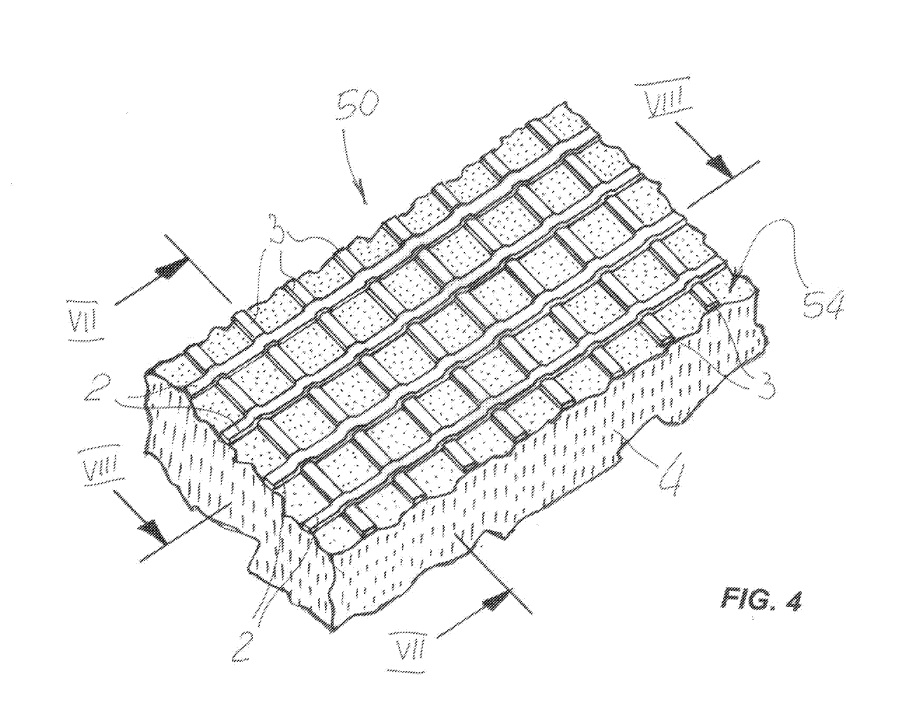

FIGS. 4, 7 and 8 show a second embodiment of a substrate, referenced 50, for making a sensitive floor according to the invention.

Like in the above described embodiment, the substrate 50 comprises a first frame of strips, generally referenced 2, and a second frame of strips, generally referenced 3, both made of aluminum, and hence having a high conductivity, which are arranged in perpendicular relationship.

Nevertheless, unlike the previous embodiment, both frames of strips 2 and 3 lie on a common face 54 of the sheet 4, typically the face designed to face upwards when the substrate 50 has been laid.

In this case, in order to prevent contact interferences between the strips 2 and 3 at their intersection points, their upward surfaces are both coated with a sheet of insulating material, typically paper or plastic, referenced 55, as best schematically shown in FIGS. 7 and 8.

Conversely, the opposite surfaces of the strips 2 and 3, i.e. those facing the face 54, have no protection, like in the previous embodiment, for contact with the face 54.

Once again, the strips 2 and 3 only contact each other at the multitude of points defined by the raised roughness 14 of the face 54 which, when no load acts upon the substrate 50, form a substantially small contact area implying a high electrical resistance contact, whereas in the loaded state, the roughness is pressed by the strips, eliminates non-contact areas 15 and directly rests upon the face 54 with a considerably larger contact area, implying a considerably lower electrical resistance contact.

The operation of the invention is as follows:

It should be noted beforehand that “electrical resistance” is related to the surface of a sample of material of known resistivity, according to the following relation:

R=1/G=L/σ.S=ρL/S

where:
R=electrical resistance;
G=electrical conductance;
L=distance between two measurement points;
ρ=electrical resistivity;
σ=electrical conductivity;
S=area of the section perpendicular to electric current.

Therefore, the electrical resistance value “R” is generally inversely proportional to the surface value “S” of the sample and changes as the latter changes, i.e. as the surface “S” increases, the electrical resistance “R” decreases.

More in detail, the strips 2a-2d and 3a-3d are initially set to the same potential, i.e. VCC/2, by the control board “SK2”, such that no current circulates therethrough (strips 2a-2d and 3a-3d).

Load conditions are detected by estimating the electric currents derived therefrom, still by means of the electronic boar “SK2”, which cyclically resets the electric potential of each strip, e.g. in the strips 3a-3d, and sequentially measures the currents that circulate in the strips 2a-2d perpendicular thereto (having a potential of VCC/2).

The potential difference established between the strip 3 that has been set to zero potential and the strips 2a-2d causes the circulation of a current whose strength depends on the electrical resistance of the interposed material, here the sheet 4 and, as mentioned above, on the contact value surface between the surfaces S3 of the strips 3a-3d and the face 104 and between the surfaces S2 of the strips 2a-2d and the face 104.

As mentioned above, when a compression force is applied to the substrate 1, the area of this contact surface instantaneously increases, which will reduce the electrical resistance between the reading strip, e.g. one of the strips 3a-3d, which behaves in this case as a detecting strip, and the strips 2a-2d, which are “detected” strips.

The decrease of the electrical resistance causes an increase of the current strength, i.e. the signal transmitted to the computer 11, which almost instantaneously translates it into a displayed graphic.

The cyclical action of the board “SK2” allows continuous display of the graphics on the computer monitor.

In other words, any pressure acting on the substrate changes, i.e. increases, the contact area between the face 104 of the sheet 4 and the bottom surfaces “S3” of each strip 3 and the top surfaces “S2” of each strip 2, and as a result the electrical resistance value, which also increases the strength of the current that circulates in the strips 2a-2d.

The latter is sensed and sent to the computer 11 through the cables 5 or 6, and the lines 9 and 10 and graphed on screen in real time.

The same applies when the functions of the strips 2a-2b and 3a-3d are reversed, i.e. with the former being reading strips and the latter being read strips.

The operation of the second embodiment of the substrate 50 is substantially the same as described for the first embodiment.

The only difference therebetween is that the strips 2 and 3 have respective contact surfaces resting on the same face 54 of the sheet 4, whereas the opposite surfaces are insulated with sheets 55 of insulating material, to avoid interferences at intersection points.

It shall be noted that, should any sensing strip be broken for any reason whatever, e.g. for some damage that causes it to be cut, the function of that strip is only missing in the substrate 1, with the function of the substrate being still active, although reduced in the area where damage has occurred.

According to a further variant of the substrate 1 or 50, not shown and understandable by intuition, one of the frames of strips may be painted on the corresponding face of the sheet, whereas the other frame is still provided in the form of applied strip.

The invention has been found to fulfill the intended objects.

The invention so conceived is susceptible to changes and variants within the inventive concept.

Also, all the details may be replaced by other technical equivalent elements.

In its practical implementation, any material, shape and size may be used as needed, without departure from the scope as defined by the following claims.

The invention claimed is:

1. A substrate (1; 50) for making a sensing floor comprising:
a first frame of high conductivity sensing elements (2a-2d) having a first orientation;
a second frame of high conductivity sensing elements (3a-3d) having a second orientation different from said first orientation, said second frame (3a-3d) providing a support layer for finishing items of a floor; and
one element (4) made of a conductive material and including:
an elastically compressible layer having a thickness (S1);
two opposing contact faces (104, 204) to contact said first and second frame (2a-2d, 3a-3d); and
an electric resistance proportional to said thickness (S1).

2. The substrate as claimed in claim 1, wherein said first frame and second frame (2a-2d, 3a-3d) comprise respective reciprocally independent connection terminals (7, 8) configured to be connected to a receiving and signal displaying device (11).

3. The substrate as claimed in claim 1, wherein said first frame and second frame each comprises a plurality of parallel strips (2a-2d, 3a-3d) made of a high conductivity metallic material.

4. The substrate as claimed in claim 3, wherein said parallel strips comprise flexible strips (2a-2d, 3a-3d).

5. The substrate as claimed in claim 3, wherein each of said terminals (7, 8) is connected to each of said parallel strips (2a-2d, 3a-3d) by respective independent connecting members (5, 6).

6. The substrate as claimed in claim 1, wherein said conductive element comprises a slab (4) made of a polymeric conductive material.

7. The substrate as claimed in claim 3, wherein said conductive element comprises a slab (4) made of a polymeric conductive material, and wherein at least one of said frame of parallel strips (2a-2d, 3a-3d) is in the form of conductive painted stripes painted on a corresponding face of said slab (4).

8. The substrate as claimed in claim 1, wherein said substrate is configured as a flexible sheath.

9. The substrate as claimed in claim 1, wherein said substrate is configured as reciprocally modular elements.

10. The substrate as claimed in claim 6, wherein said slab (4) is fitted between said first frame and second frame of strips (2a-2d, 3a-3d).

11. The substrate as claimed in claim 6, wherein said slab (4) is fitted under said first and second frames of strips (2a-2d, 3a-3d).

12. A continuously sensing and displaying method of a load on a sensing substrate (1; 50) for making a sensing floor, comprising the steps of:
feeding by a constant electric potential a first frame and a second frame of high electro-conductivity sensing elements (2a-2d, 3a-3d) having intersecting orientations and in contact with a conductive layer (4) of a polymeric material through a first contact area thereof, which has a first electric resistance in an unloaded condition;
loading said substrate (1; 50) with a load;
modifying said first contact area in a loading condition, obtaining a second modified and larger contact area, and said first electric resistance obtaining a second modified lower resistance;
zeroing by cyclic zero settings said electric potential in each of said sensing elements (2a-2d, 3a-3d);
sequentially measuring current intensity in the remaining sensing elements at every cyclic zero settings, to sense current intensity variations rising from said modifications of said electric resistance;
transducing said current intensity modifications into continuous signals; and
carrying said signals on a continuously displaying device (11) by carrying members.
